(19) United States
(12) Patent Application Publication
(10) Pub. No.: US 2026/0256025 A1
(43) Pub. Date: Aug. 27, 2026

(54) SEMICONDUCTOR MEMORY AND MANUFACTURING METHOD THEREOF

(71) Applicant: Kioxia Corporation, Tokyo (JP)

(72) Inventor: Kana KUDO, Yokohama Kanagawa (JP)

(73) Assignee: Kioxia Corporation, Tokyo (JP)

(21) Appl. No.: 19/312,489

(22) Filed: Aug. 28, 2025

(30) Foreign Application Priority Data
Feb. 21, 2025 (JP) 2025-026363

(51) Int. Cl. H01L 23/00; H01L 25/18; H10B 80/00; H10D 80/30

(52) U.S. Cl. CPC H10W 90/00; H10B 80/00; H10D 80/30; H10W 72/073; H10W 72/07332; H10W 72/07352; H10W 72/07353; H10W 72/07354; H10W 72/327; H10W 72/334; H10W 72/337; H10W 72/347; H10W 72/865; H10W 72/884; H10W 90/24; H10W 90/732; H10W 90/733; H10W 90/734; H10W 90/752; H10W 90/754

(57) ABSTRACT

A semiconductor memory includes a substrate having a first face; a controller chip mounted on the first face of the substrate; an adhesive layer covering at least a portion of the controller chip and a portion of the substrate; a first memory chip attached onto the substrate and the controller chip across the adhesive layer; and a second memory chip stacked on the first memory chip. The adhesive layer is in contact with at least one portion of a side face of the first memory chip and at least one portion of a bottom face of the second memory chip.

### CROSS-REFERENCE TO RELATED APPLICATION(S)

This application is based upon and claims the benefit of priority from Japanese Patent Application No. 2025-026363, filed Feb. 21, 2025, the entire contents of which are incorporated herein by reference.

### FIELD

Embodiments described herein relate generally to a semiconductor memory, and to a manufacturing method thereof.

### BACKGROUND

A semiconductor memory such that a multiple of memory chips, and a controller that controls a read of data from the memory chips and a write of data onto the memory chips, are integrated is already known.

### DESCRIPTION OF THE DRAWINGS

FIG. 1 is a sectional view of a semiconductor memory of a first embodiment.

FIG. 2 is a top view of the semiconductor memory of the first embodiment.

FIG. 3 is a sectional view showing a first process of a method of manufacturing the semiconductor memory of the first embodiment.

FIG. 4 is a sectional view showing a process after FIG. 3 of the method of manufacturing the semiconductor memory of the first embodiment.

FIG. 5 is a sectional view showing a process after FIG. 4 of the method of manufacturing the semiconductor memory of the first embodiment.

FIG. 6 is a sectional view showing a process after FIG. 5 of the method of manufacturing the semiconductor memory of the first embodiment.

FIG. 7 is a sectional view showing a process after FIG. 6 of the method of manufacturing the semiconductor memory of the first embodiment.

FIG. 8 is a sectional view of a semiconductor memory of a second embodiment.

FIG. 9 is a top view of the semiconductor memory of the second embodiment.

FIG. 10 is a sectional view of a semiconductor memory of a third embodiment.

FIG. 11 is a top view of the semiconductor memory of the third embodiment.

FIG. 12 is a sectional view of a semiconductor memory of a modification of the third embodiment.

### DETAILED DESCRIPTION

Embodiments provide a semiconductor memory with few problems, and a manufacturing method thereof, can be obtained.

In general, according to one embodiment, a semiconductor memory includes a substrate having a first face; a controller chip mounted on the first face of the substrate; an adhesive layer covering at least a portion of the controller chip and a portion of the substrate; a first memory chip attached onto the substrate and the controller chip across the adhesive layer; and a second memory chip stacked on the first memory chip. The adhesive layer is in contact with at least one portion of a side face of the first memory chip and at least one portion of a bottom face of the second memory chip.

Hereafter, exemplifying embodiments of a semiconductor memory will be disclosed. Configurations and methods (technical characteristics) of the embodiments shown below, and effects and results (advantages) provided by the configurations and methods, are examples. Also, the same configurations are included in the multiple of embodiments given as examples below. Therefore, the same effects and advantages based on the same configurations are obtained in each embodiment. Hereafter, identical reference signs will be allotted to identical components, and redundant descriptions will be omitted.

### First Embodiment

A first embodiment relates to a semiconductor memory, and to a semiconductor memory manufacturing method.

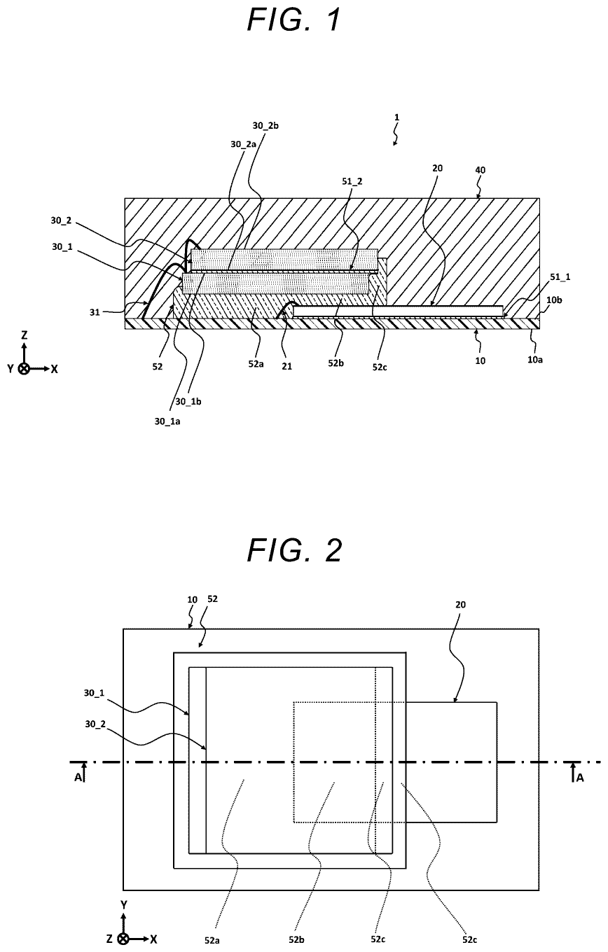

FIG. 1 is a sectional view along an XZ plane of a semiconductor memory 1. FIG. 2 is a top view of the semiconductor memory 1 seen from a Z direction. FIG. 2 shows a case in which a cover layer 40 is removed. Arrows showing directions are depicted in each drawing. An X direction X, a Y direction Y, and a Z direction are perpendicular to each other. The X direction and the Y direction are directions following a back face 10a and a front face 10b of a substrate 10, and the Z direction is a thickness direction of the substrate 10.

FIG. 1 is a sectional view along a section line A-A shown in FIG. 2.

As shown in FIG. 1, the semiconductor memory 1 includes the substrate 10, a controller (chip) 20, a multiple of memory chips 30 (30_1 and 30_2), and the cover layer 40. Herein, a case in which there are two memory chips 30 is shown as an example, but the number of memory chips 30 provided in the semiconductor memory 1 is not limited to two.

The substrate 10, being a circuit substrate, is, for example, a printed wiring board. The substrate 10 has a flattened plate form, and has the back face 10a and the front face 10b, which are parallel to each other. Each of the back face 10a and the front face 10b intersects the Z direction, and is approximately perpendicular to the Z direction.

The controller 20 controls a read of data from the memory chip 30 and a write of data into the memory chip 30. The controller 20 may also execute a control other than the read and write. Also, the controller 20 is a chip that has a flattened cuboid form, and has a back face and a front face that are parallel to each other. Each of the back face and the front face of the controller 20 intersects the Z direction, and is approximately perpendicular to the Z direction.

The controller 20 is mounted on the front face 10b of the substrate 10. The controller 20 may, for example, be bonded onto the front face 10b via an adhesive layer 51_1. The adhesive layer 51_1 is interposed between the front face 10b and the controller 20, and bonds the front face 10b and the controller 20. The adhesive layer 51_1 may be provided using a die attach film. The adhesive layer 51_1 is provided on a back face of a wafer (not shown) in which regions of a multiple of controllers 20 are integrated during a process of manufacturing the controller 20. The wafer is cut by dicing, thereby being divided into a multiple of controllers 20, and the adhesive layer 51_1 is provided on a face of each controller 20 on the substrate 10 side. Also, the controller 20 is electrically connected to a conductive portion (not shown) like, for example, a wiring pattern of the substrate 10 via a bonding wire 21.

The memory chip 30, being a non-volatile memory, is, for example, a NAND flash memory. The memory chip 30_1 has a flattened cuboid form, and has a back face 30_1a and a front face 30_1b that are parallel to each other. Each of the back face 30_1a and the front face 30_1b intersects the Z direction, and is approximately perpendicular to the Z direction in the present embodiment. The memory chip 30_2, in the same way as the memory chip 30_1, has a flattened cuboid form, and has a back face 30_2a and a front face 30_2b that are parallel to each other. Each of the back face 30_2a and the front face 30_2b intersects the Z direction, and is approximately perpendicular to the Z direction in the present embodiment.

The memory chip 30_1 and the memory chip 30_2 are, for example, bonded via an adhesive layer 51_2. The adhesive layer 51_2 is interposed between the front face 30_1b and the back face 30_2a, and bonds the memory chip 30_1 and the memory chip 30_2. The adhesive layer 51_2 may be provided using a die attach film. Also, each of the memory chip 30_1 and the memory chip 30_2 is electrically connected to a conductive portion (not shown) like, for example, a wiring pattern of the substrate 10 via a bonding wire (memory chip) 31.

The memory chip 30_1 and the memory chip 30_2 partially cover the controller 20. In other words, the memory chip 30_1 and the memory chip 30_2 partially coincide with the controller 20 in the Z direction.

An adhesive layer 52 is interposed between the memory chip 30_1 and the front face 10b and between the memory chip 30_1 and the controller 20, and bonds the substrate 10 and the memory chip 30_1. As a die attach film is used as the adhesive layer 52 in the present embodiment, the adhesive layer 52 will also be called the DAF 52 in the following description. A film-form adhesive layer such as the DAF 52 is preferred as an adhesive layer, but, not being limited to a film-form adhesive layer, an adhesive layer is not limited to being a die attach film, provided that advantages of the disclosure the same as those of the DAF 52 are obtained.

As shown in FIG. 1, a thickness of the DAF 52 in the Z direction is greater than a thickness of the controller 20 in the Z direction. The aforementioned thickness of the DAF 52 may be obtained by using one thick die attach film, or the aforementioned thickness may be obtained by stacking a multiple of die attach films.

The DAF 52 has a first region 52a, a second region 52b, and a third region 52c. The first region 52a is a region that covers the front face 10b outside the controller 20, and is a region that coincides with the back face 30_1a in the Z direction. The first region 52a bonds the front face 10b and the back face 30_1a. The second region 52b is a region positioned on the controller 20, and is a region that coincides with the back face 30_1a in the Z direction. The second region 52b bonds the controller 20 and the back face 30_1a. The third region 52c is positioned on the controller 20 in the Z direction, but is a region outside the back face 30_1a.

In a top view seen from the Z direction, the first region 52a is wider than the second region 52b, as shown in FIG. 2. The second region 52b is wider than the third region 52c.

The cover layer 40 is provided on the front face 10b of the substrate 10, and covers the substrate 10. The cover layer 40 and the substrate 10 enclose the controller 20, the memory chip 30_1, and the memory chip 30_2. The cover layer 40 is made of an insulating synthetic resin material. The synthetic resin material is, for example, an epoxy resin mixed with an inorganic substance such as silicon dioxide. The cover layer 40 may also be called a sealing resin or a resin mold. The cover layer 40 is configured with a material differing from that of the DAF 52.

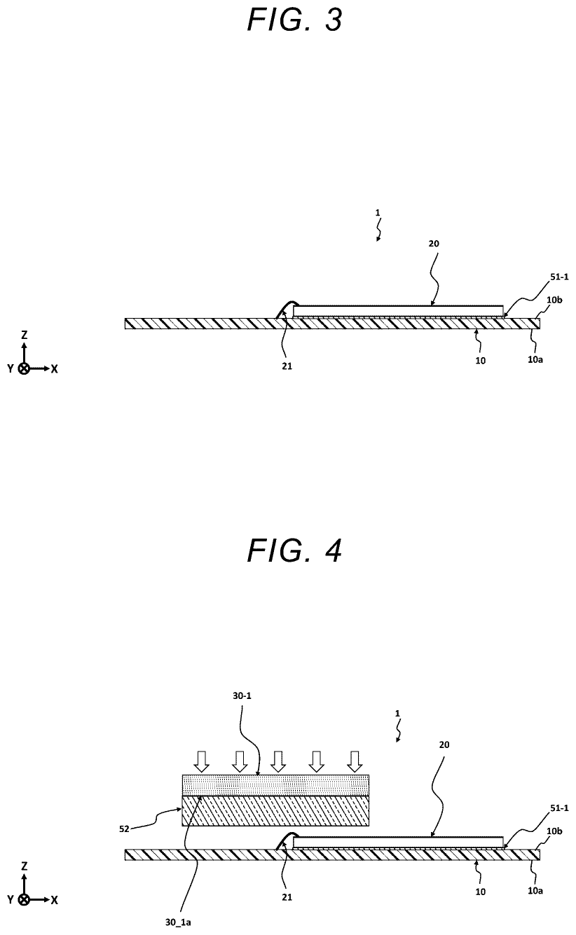

FIGS. 3 to 6 show a process of manufacturing the semiconductor memory 1. First, as shown in FIG. 3, the controller 20 is mounted on the front face 10b of the substrate 10. The controller 20 is bonded onto the front face 10b via the adhesive layer 51_1. Also, wire bonding is performed, whereby the controller 20 is electrically connected to a conductive portion (not shown) of the substrate 10 via the bonding wire (controller) 21. The controller 20 may also be electrically connected to the conductive portion (not shown) of the substrate 10 using a flip-chip connection.

Next, as shown in FIG. 4, the DAF 52 is bonded to 30_1a, which is the back face of the memory chip 30_1. As the DAF 52 is configured with a film material, a thickness thereof is uniform. The memory chip 30_1 and the DAF 52 are pressed toward the front face 10b of the substrate 10, that is, in a direction opposite to the Z direction. This process of being pressed is a first pressing process.

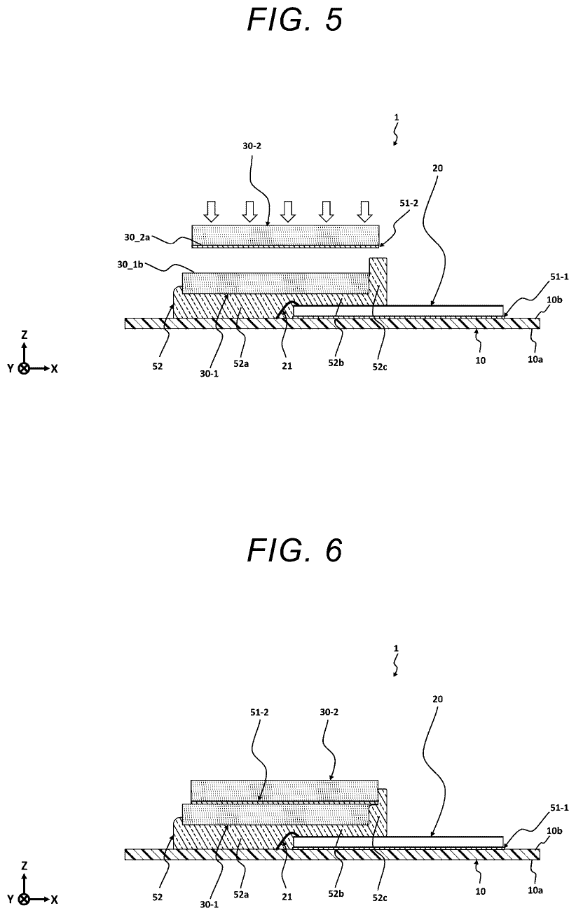

In FIG. 5, the semiconductor memory 1 after the first pressing process is shown. The DAF 52 is bonded by the first pressing process in such a way as to cover the front face 10b of the substrate 10 and one portion of the controller 20. Also, the DAF 52 is compressed by the first pressing process in such a way that a height of an upper face in the Z direction of a pressed portion is lowered evenly, and the DAF 52 expands to an outer side along the front face 10b of the substrate 10 toward a perimeter. Herein, a thickness in the Z direction of the second region 52b is smaller compared with a thickness in the Z direction of the first region 52a by an amount equivalent to the thickness in the Z direction of the controller 20. Because of this, one portion of the DAF 52 existing in the second region 52b before the first pressing process is led to an outer side of the second region 52b by the first pressing process, and the DAF 52 flows into the third region 52c. The DAF 52 forms a protrusion in the third region 52c. As shown in FIG. 5, the third region 52c covers a side face of the memory chip 30_1.

Next, as shown in FIG. 5, the adhesive layer 51_2 is bonded to 30_2a, which is the back face of the memory chip 30_2. Subsequently, the memory chip 30_2 and the adhesive layer 51_2 are pressed toward the front face 30_1b of the memory chip 30_1, that is, in a direction opposite to the Z direction. This process of being pressed is a second pressing process.

In FIG. 6, the semiconductor memory 1 after the second pressing process is shown. The third region 52c of the DAF 52 comes into contact with a bottom face of the memory chip 30_2 owing to the second pressing process. Subsequently, a portion of the third region 52c pressed by a lower face of the memory chip 30_2 is led to a side face side of the memory chip 30_2, and covers a side face of the memory chip 30_2. The DAF 52 is solidified in the state of FIG. 6.

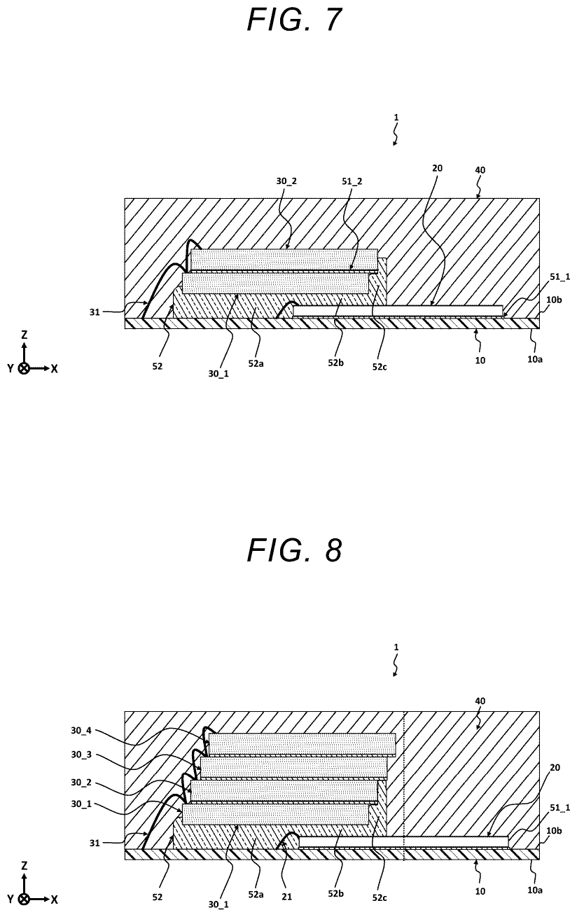

Next, as shown in FIG. 7, the cover layer 40 is formed on the front face 10b of the substrate 10, and the cover layer 40 covers the front face 10b of the substrate 10, the two memory chips 30, and the controller 20. Because of this, the controller 20 and the two memory chips 30 are enclosed by the substrate 10 and the cover layer 40.

In the present embodiment, as heretofore described, the memory chip 30_2 is mounted on the memory chip 30_1. When doing so, fixing of the memory chip 30_2 is stabilized by the third region 52c of the DAF 52 supporting the memory chip 30_2 from a lower side, or further supporting the memory chip 30_2 from a side face too. When a second-level stacked memory chip is not supported as in the present embodiment from a lower side and a side face by the third region 52c, distortion occurs in a step between the stacked memory chips, stress is liable to be exerted, and a weight of the memory chip stacked on the upper stage is applied to the memory chip on the lower stage. There is concern that a second-level stacked memory chip not being supported as in the present embodiment from a lower side and a side face by the third region 52c is one cause of chip cracking in a semiconductor memory.

With regard to this, according to the present embodiment, stress can be dispersed to an extent by which the memory chip 30_2 is supported by the third region 52c. In addition, the third region 52c can support the stepped portion between the memory chip 30_1 and the memory chip 30_2, where stress is especially liable to be exerted, because of which an occurrence of chip cracking can be restricted. That is, according to the present embodiment, for example, the third region 52c is created by bonding the memory chip 30_1 and the substrate 10 using the DAF 52, and an advantage is obtained in that the memory chip 30_2 can be stably supported by the third region 52c.

Also, when the DAF 52 is not used as in the present embodiment, it is necessary to mount a spacer on a substrate, and mount a memory chip on the spacer. Meanwhile, according to the present embodiment, there is no need to mount a spacer on the substrate 10. This means that according to the present embodiment, for example, spacer costs are restricted, and manufacturing time and effort can be reduced.

### Second Embodiment

Hereafter, the semiconductor memory 1 according to a second embodiment will be described. Each portion of a semiconductor memory according to the second embodiment that is identical to a portion of the semiconductor memory 1 according to the first embodiment will be indicated by an identical reference sign. A detailed description of portions duplicated in the semiconductor memory according to the second embodiment and the semiconductor memory according to the first embodiment will be omitted.

FIG. 8 is a sectional view along the Z direction of the semiconductor memory 1 according to the second embodiment. The semiconductor memory 1 according to the second embodiment includes a greater number of memory chips 30 compared with the first embodiment. FIG. 8 shows an example in which four memory chips 30 (30_1 to 30_4) are included. Also, the semiconductor memory 1 may be manufactured using the same manufacturing process in the second embodiment too. The memory chips are stacked at a constant distance from each other. The third region 52c may come into contact with a bottom face of the memory chip 30_3.

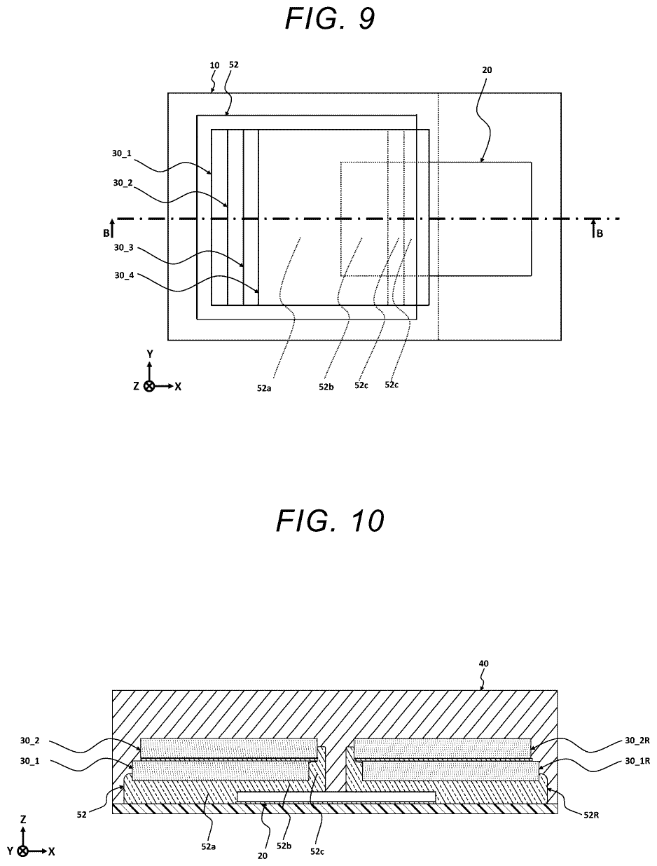

FIG. 9 is a top view of the semiconductor memory 1 seen in a direction opposite to the Z direction. FIG. 9 shows a case in which the cover layer 40 is removed. FIG. 8 is a sectional view along a section line B-B shown in FIG. 9. As shown in FIGS. 8 and 9, a maximum coordinate of the uppermost memory chip 30_4 in the X direction is smaller than a coordinate of a center of gravity of the controller 20 in the X direction.

According to this kind of configuration, a greater number of memory chips 30 can be stacked, because of which a memory capacity increases, leading to an improvement in performance of the semiconductor memory 1. In the second embodiment, distortion and stress occurring in the memory chip 30 is greater than in the first embodiment due to a greater number of memory chips 30 being stacked than in the case of the first embodiment, but stress can be alleviated by the third region 52c. Also, owing to the maximum coordinate of the uppermost memory chip 30_4 in the X direction being smaller than the coordinate of the center of gravity of the controller 20 in the X direction, distortion and stress occurring in the memory chip 30 is reduced, and fixing of the stacked memory chips 30 stabilizes.

### Third Embodiment

Hereafter, the semiconductor memory 1 according to a third embodiment will be described. Each portion of a semiconductor memory according to the third embodiment that is identical to a portion of the semiconductor memory 1 according to the first embodiment will be indicated by an identical reference sign. A detailed description of portions duplicated in the semiconductor memory according to the third embodiment and the semiconductor memory according to the first embodiment will be omitted.

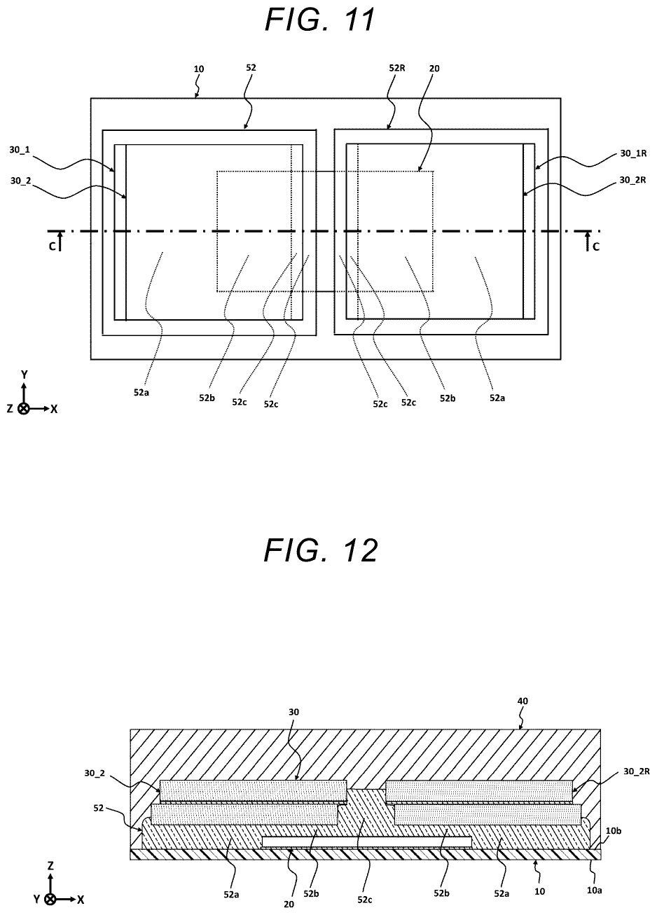

FIG. 10 is a sectional view along the Z direction of the semiconductor memory 1 according to the third embodiment. Compared with the first embodiment, the semiconductor memory 1 according to the third embodiment further includes a DAF 52R and a multiple of memory chips 30 (30_1R and 30_2R). FIG. 11 is a top view of the semiconductor memory 1 according to the third embodiment seen in a direction opposite to the Z direction. FIG. 11 shows a case in which the cover layer 40 is removed. FIG. 10 is a sectional view along a section line B-B shown in FIG. 11. The semiconductor memory 1 may be manufactured using the same manufacturing process as in the first embodiment in the third embodiment too.

The upper memory chip 30_2 is disposed in such a way as not to come into contact with the other memory chip 30_2R. That is, a maximum coordinate of the memory chip 30_2 in the X direction is smaller than the coordinate of the center of gravity of the controller 20 in the X direction, and a minimum coordinate of the memory chip 30_2R in the X direction is greater than the coordinate of the center of gravity of the controller 20 in the X direction.

According to this kind of configuration, a greater number of memory chips 30 can be mounted compared with a semiconductor memory according to the first embodiment, because of which a memory capacity increases, leading to an improvement in performance of the semiconductor memory 1.

### Third Embodiment Modification

Also, a configuration such that one large DAF 52 is used instead of the DAF 52 and the DAF 52R, and the DAF 52 is connected in the center, may be adopted. FIG. 12 is a sectional view along the Z direction of the semiconductor memory 1 according to a modification of the third embodiment. The semiconductor memory 1 may be manufactured using the same manufacturing process as in the first embodiment in the modification of the third embodiment too. The DAF 52 is bonded in such a way as to cover all of the front face 10b of the substrate 10 and the controller 20.

In the modification of the third embodiment, the DAF 52 previously in left and right second regions 52b is led by a first pressing process to the third region 52c between left and right memory chips. Therefore, the amount of the DAF 52 existing in the third region 52c increases.

According to this kind of configuration, the third region 52c of the DAF 52 can support the memory chip 30_2 and the memory chip 30_2R from a lower side. Furthermore, the left and right memory chip 30_2 and memory chip 30_2R can also support each other from side faces across the third region 52c of the DAF 52. In addition, the amount of the DAF 52 in the third region 52c is greater in comparison with the third embodiment, because of which a greater stress can be caused to disperse, and an occurrence of chip cracking can be restricted.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory, comprising:
a substrate having a first face;
a controller chip mounted on the first face of the substrate;
an adhesive layer covering at least a portion of the controller chip and a portion of the substrate;
a first memory chip attached onto the substrate and the controller chip across the adhesive layer; and
a second memory chip stacked on the first memory chip, wherein
the adhesive layer is in contact with at least one portion of a side face of the first memory chip and at least one portion of a bottom face of the second memory chip.

2. The semiconductor memory according to claim 1, wherein the adhesive layer is in contact with at least one portion of a side face of the second memory chip.

3. The semiconductor memory according to claim 2, further comprising a third memory chip, wherein
the third memory chip is stacked on the second memory chip, and
the adhesive layer is in contact with a bottom face of the third memory chip.

4. The semiconductor memory according to claim 1, wherein the first memory chip, when viewed from the top, shares a first area with the controller chip, and the first area is smaller than one-half of a second area of the controller chip when seen from the first direction.

5. The semiconductor memory according to claim 4, wherein the second memory chip, when seen from the top, shares a third area with the controller chip, and the third area is smaller than one-half of the second area.

6. The semiconductor memory according to claim 3, wherein the first memory chip, when viewed from the top, shares a first area with the controller chip, and the first area is smaller than one-half of a second area of the controller chip when seen from the first direction,
the second memory chip, when viewed from the top, shares a third area with the controller chip, and the third area is smaller than one-half of the second area, and
the third memory chip, when viewed from the top, shares a fourth area with the controller chip, and the fourth area is smaller than one-half of the second area.

7. The semiconductor memory according to claim 1, further comprising:
a fourth memory chip attached onto the substrate and the controller chip across the adhesive layer; and
a fifth memory chip stacked on the fourth memory chip, wherein
the adhesive layer is in contact with at least one portion of a side face of the fourth memory chip, and is in contact with at least one portion of a bottom face of the fifth memory chip.

8. The semiconductor memory according to claim 1, wherein
the adhesive layer, when viewed from the top, includes a protrusion overlaying the controller chip but not overlaying the first memory chip.

9. The semiconductor memory according to claim 1, wherein
a thickness of the adhesive layer is greater than a thickness of the controller chip.

10. The semiconductor memory according to claim 1, wherein
the adhesive layer is a film-form adhesive.

11. The semiconductor memory according to claim 1, wherein
the adhesive layer includes a multiple of die attach films stacked one top of one another.

12. A semiconductor memory, comprising:
a substrate having a first face;
a controller chip mounted on the first face of the substrate;
an adhesive layer covering at least a portion of the controller chip and a portion of the substrate;
a first memory chip attached onto the substrate and the controller chip across the adhesive layer; and
a second memory chip stacked on the first memory chip, wherein
the adhesive layer includes, when viewed from the top, a protrusion overlaying the controller chip but not overlaying the first memory chip, and
the adhesive layer is in contact with at least one portion of a side face of the first memory chip, and is in contact with at least one portion of a bottom face and at least one portion of a side face of the second memory chip.

13. The semiconductor memory according to claim 12, wherein
the first memory chip shares a first area with the controller chip when viewed from the top, and the first area is smaller than one-half of a second area of the controller chip when seen from the first direction, and
the second memory chip shares a third area with the controller chip when viewed from the top, and the third area is smaller than one-half of the second area.

14. The semiconductor memory according to claim 13, wherein
the second memory chip, when viewed from the top, is stacked on the first memory chip,
a thickness of the adhesive layer is greater than a thickness of the controller chip, and
the adhesive layer includes a multiple of die attach films stacked one top of one another.

15. A semiconductor memory manufacturing method, comprising:
mounting a controller chip on a first face of a substrate;
providing an adhesive layer to cover at least one portion of the controller chip and one portion of the substrate;
pressing the first memory chip via the adhesive layer in a first direction perpendicular to the first face and an upper face of the controller chip;
bonding the second memory chip to the first memory chip, such that a bottom side of the second memory chip comes into contact with the adhesive layer and the adhesive layer extends along a portion of a side face of the second memory chip; and
covering at least the controller chip, the first memory chip, and the second memory chip with a cover layer, such that the controller chip, the first memory chip, and the second memory chip are enclosed between the substrate and the cover layer.

16. The semiconductor memory manufacturing method according to claim 15, wherein
the adhesive layer is led to the controller chip side as seen from the first memory chip by the first memory chip being pressed in the first direction.

17. The semiconductor memory manufacturing method according to claim 15, wherein
a protrusion of the adhesive layer is formed in a place on the controller chip that is not on the first memory chip when seen from the first direction.

18. The semiconductor memory manufacturing method according to claim 15, wherein,
after bonding the second memory chip to the first memory chip, the third memory chip is bonded to the second memory chip in such a way that a bottom side of the third memory chip comes into contact with the adhesive layer protruding along a side face of the second memory chip.
